(19) United States
(12) Patent Application Publication
(10) Pub. No.: US 2026/0206524 A1
(43) Pub. Date: Jul. 16, 2026

(54) APPARATUS AND METHOD FOR DIE-TO-WAFER BONDING

(71) Applicant: Tokyo Electron Limited, Tokyo (JP)

(72) Inventors: Christopher Michael Netzband, Albany, NY (US); Adam James Gildea, Albany, NY (US); Ilseok Son, Albany, NY (US)

(21) Appl. No.: 19/019,330

(22) Filed: Jan. 13, 2025

(51) Int. Cl. H10P 72/00; H10D 88/00

(52) U.S. Cl. CPC H10P 72/0446; H10D 88/01

(57) ABSTRACT

A method is provided for die-to-wafer bonding. The method includes placing a wafer over a first side of a flexible wafer chuck, where the flexible wafer chuck has the first side and an opposite second side. The method includes pushing the flexible wafer chuck from the second side using a first plunger to create a locally protruding region on the wafer. A die is placed on the locally protruding region of the wafer. The method further includes bonding the die to the wafer at the locally protruding region. The locally protruding region enables precise control of the bonding interface between the die and wafer, improving bonding quality and reliability.

### TECHNICAL FIELD

The present invention relates generally to an apparatus and method in semiconductor manufacturing, and, in particular embodiments, to an apparatus and method for die-to-wafer bonding process.

### BACKGROUND

Die-to-wafer (D2W) bonding process in semiconductor manufacturing is used to integrate individual dies onto a larger wafer substrate. A die refers to a small block of semiconductor material that contains the circuitry necessary for a specific electronic function. D2W bonding enables the combination of diverse semiconductor technologies within a single platform, essential for creating advanced multi-die assemblies and system-on-chip applications. Die-to-wafer bonding supports the development of heterogeneous integrations, where different types of semiconductor dies with different functionalities are combined to enhance device performance and efficiency. This process is widely applied in fabricating high-density electronic packages, including memory modules, microprocessors, and various miniaturized devices, meeting the growing demand for compact and powerful electronic solutions.

### SUMMARY

In accordance with one aspect of the present invention, a method is provided for die-to-wafer bonding. The method includes placing a wafer over a first side of a flexible wafer chuck, where the flexible wafer chuck has the first side and an opposite second side. The method further includes pushing the flexible wafer chuck from the second side using a first plunger to form a locally protruding region on the wafer. A die is placed on the locally protruding region of the wafer, and the die is bonded to the wafer at the locally protruding region.

In accordance with another aspect of the present invention, a die-to-wafer bonding apparatus is provided. The apparatus includes a wafer chuck and a first plunger configured to operate in two operational states. In the first operational state, the first plunger is configured to locally deform the wafer chuck to form a locally protruding region. In the second operational state, the first plunger is configured to remove the locally protruding region.

In accordance with yet another aspect of the present invention, a die-to-wafer bonding apparatus is provided. The apparatus includes a wafer chuck and a channel plate configured to be coupled to the wafer chuck. The channel plate includes a first channel coupled to a gas flow line and a second channel coupled to a vacuum line. One or more controllers are configured to deform the wafer chuck to form a locally protruding region. The controllers achieve this by coupling a vacuum pump to the vacuum line to hold the wafer chuck with the channel plate, and fluidly coupling the gas flow line to a gas tank to form a gas pocket between the wafer chuck and the channel plate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a schematic cross sectional view of a die-to-wafer bonding apparatus, in accordance with an embodiment;

FIGS. 2A-2B are schematic cross sectional and top views of a local protruding system of FIG. 1, in accordance with an embodiment;

FIGS. 3A-3B are schematic cross sectional and top views of a local protruding system variation of FIG. 1, in accordance with an embodiment;

FIGS. 4A-4B are schematic cross sectional and top views of another local protruding system variation of FIG. 1, in accordance with an embodiment;

FIG. 5 is a schematic cross sectional view of a die-to-wafer bonding apparatus variation, in accordance with an embodiment;

FIG. 6A is a schematic cross sectional view of another die-to-wafer bonding apparatus variation, in accordance with an embodiment;

FIG. 6B is a top view of a channel plate of FIG. 6A, in accordance with an embodiment;

FIGS. 7A-7F are schematic cross sectional views of a die-to-wafer bonding process, in accordance with an embodiment;

### DETAILED DESCRIPTION OF ILLUSTRATIVE EMBODIMENTS

During die-to-wafer (D2W) bonding processes, the center of the die is brought into contact with a carrier wafer and subsequent bond propagation is driven by Van der Waals interactions. The forces driving the propagation of this bond will cause the die to stretch, creating a scaling misalignment between the die and the carrier pattern after the bond is complete. To ensure that the initiation occurs at the center of the die it is flexed. This flexure increases the distance the bond wave must travel across the die creating further scaling misalignment. Finally, this scaling effect becomes more pronounced in faster bonding processes due to increased attractive forces between the die and the wafer. The combined outcome of these features of the D2W process is that scaling accounts for a major proportion of total misalignment and subsequent device performance degradation. While wafer-to-wafer (W2W) bonding allows for corrections by flexing the lower wafer, D2W bonding currently lacks a comparable solution to address the scaling issue from the carrier wafer side.

In various embodiments of this disclosure, a flexible wafer chuck may mitigate this scaling issue during bonding process. By allowing the chuck to flex, the pressure applied to the wafer chuck can induce a local elastic deformation of the wafer, forming a locally protruding region. If the shape and size of the area is precisely controlled to align with the scaling of die, both the wafer and the die can experience equal scaling during bonding, ensuring proper alignment. This approach may allow for bonding with a flat die, initiating contact at the center and allowing controlled stretching to the proper width, potentially eliminating excess scaling caused by pre-shaped dies.

Embodiments of this application describe apparatuses and methods for die-to-wafer bonding using a flexible wafer chuck that enables local protruding to counter scaling of die. Such local protruding is achieved by applying pressure to the flexible wafer chuck using plungers or gas pockets, as will be described in more detail below.

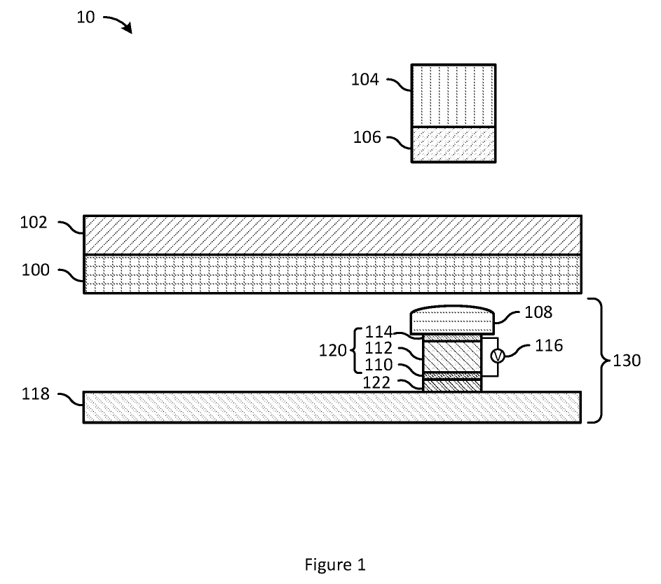

FIG. 1 illustrates a schematic view of a die-to-wafer bonding apparatus 10, in accordance with an embodiment.

The apparatus 10 may comprise a flexible wafer chuck 100 configured to securely hold a wafer 102. The wafer 102 may be a blank silicon wafer, a silicon-on-insulator (SOI) wafer, a gallium arsenide wafer, a silicon carbide wafer, a quartz wafer, or any of various other semiconductor wafers. The wafer 102 may also be coated or layered with any number of additional materials, including compound semiconductors, metals, metal oxides, or metal nitrides.

The flexible wafer chuck 100 may comprise ceramic materials such as oxides, carbides, or nitrides. In some embodiments, the surface of the flexible wafer chuck 100 facing the wafer 102 may be coated with materials like silicon carbide (SiC). The flexible wafer chuck 100 may be rigid enough to hold the wafer 102 securely to prevent unwanted displacement during bonding process. It may be flexible enough to stretch from 1 to 100 micrometer through elastic deformation. This flexibility may allow the flexible wafer chuck 100 to deform locally to counter scaling of die.

In some embodiments, a vacuum system may be coupled to the flexible wafer chuck 100 and configured to establish a vacuum zone between the flexible wafer chuck 100 and the wafer 102. The vacuum zone may enable the flexible wafer chuck 100 to securely hold the wafer 102 in place during the bonding process.

The apparatus 10 may further comprise a die chuck 104 configured to securely hold a die 106. The die 106 may be formed by singulating a large wafer into individual pieces and contain complete circuitry necessary for functioning as a standalone chip or component. The die 106 may be square or rectangular shaped and comprise semiconductor materials such as silicon, gallium arsenide, silicon carbide, or the like. The die 106 may also be coated or layered with any number of additional materials, including compound semiconductors, metals, metal oxides, or metal nitrides, to meet specific functional requirements.

The die chuck 104 may be made from rigid materials such as stainless steel, aluminum, or ceramics such as alumina, zirconia, or the like. In some embodiments, a vacuum system may be coupled to the die chuck 104 and configured to establish a vacuum zone between the die chuck 104 and the die 106. The vacuum zone may enable the die chuck 104 to securely hold the die 106 in place during bonding process.

The apparatus 10 may further comprise a local protruding system 130 to create a locally protruding region on the wafer 102. In one or more embodiments, the local protruding system 130 may comprise a first plunger 108, a first piezoelectric actuator 120, and a support platform 118 to apply pressure to the flexible wafer chuck 100.

The first plunger 108 may comprise machined metals such as stainless steel, aluminum, or ceramics such as alumina, zirconia, or the like. The first plunger 108 may be rigid enough to push the flexible wafer chuck 100 to form locally protruding regions meeting required size and shape. The top surface of the first plunger 108 may be polished to ensure an even pressure distribution to the flexible wafer chuck 100, minimizing the risk of scratches or indentations during bonding process.

The first piezoelectric actuator 120 may be configured to control the pressure applied by the first plunger 108 to the flexible wafer chuck 100. The first piezoelectric actuator 120 may comprise a first top electrode 114 disposed over a first bottom electrode 110. The first bottom electrode 100 and the first top electrode 114 may comprise any suitable conductive materials such as aluminum, nickel, copper, aluminum, silver, gold, platinum, tungsten, indium tin oxide, fluorine-doped tin oxide, or the like. The first piezoelectric actuator 120 may be coupled to the first plunger 108 through the first top electrode 114. The movement of the first top electrode 114 may induce corresponding movement of the first plunger 108 towards or away from the flexible wafer chuck 100. In certain embodiments, the first piezoelectric actuator 120 may be designed horizontally, wherein the poisson effect may be used to push the first plunger 108 in the orthogonal direction. In such embodiments, the electrodes may be on the sides of the first piezoelectric actuator 120.

The first piezoelectric actuator 120 may further comprise a first piezoelectric layer 112 disposed between the first bottom and the first top electrodes 110 and 114. The first piezoelectric layer 112 may comprise any suitable piezoelectric materials such as lead zirconate titanate, barium titanate, lead titanate, sodium potassium niobite, gallium nitride, zinc oxide, polyvinylidene fluoride, or the like. The thickness of the first piezoelectric layer 112 may change when exposed to an electric field due to the piezoelectric effect.

The first piezoelectric actuator 120 may further comprise a first voltage controller 116 coupled to the first bottom and the first top electrodes 110 and 114. In some embodiments, the first voltage controller 116 may apply voltage between the first bottom and the first top electrodes 110 and 114 to actuate the first piezoelectric layer 112 by generating an electric field within the first piezoelectric layer 112. Due to the piezoelectric effect, this electric field may expand the thickness of the first piezoelectric layer 112, moving the first plunger 108 to push the flexible wafer chuck 100. The pressure may locally deform the flexible wafer chuck 100, inducing a locally protruding region on the wafer 102. Controlling the voltage applied between the first bottom and the first top electrodes 110 and 114 may control the pressure applied to the flexible wafer chuck 100. This may further adjust the top surface of the locally protruding region facing the die 106 that may correspond to the footprint of the die 106. This adjustment helps counter the scaling of the die 106 during bonding process, leading to improved alignment and manufacturing quality.

Using the first piezoelectric actuator 120 to control the movement of the first plunger 108 may enable precise positioning within nanometer ranges due to high sensitivity of piezoelectric materials to electric field. Moreover, the first piezoelectric actuator 120 can be manufactured to vary in size from a few millimeters to a few centimeters in both length and thickness, providing adaptability in constrained spaces and broad movement ranges. This flexibility may particularly benefit the application in die-to-wafer bonding, where the area of bonding region may range from millimeters to centimeters, while addressing scales of die scaling in nanometers to micrometers.

In various embodiments, the die chuck 104 may maintain consistent alignment with the first plunger 108. During operation, the die chuck 104 may move to pick up the die 106 and return to align with the first plunger 108 at a predetermined position. In one or more embodiments, the alignment of the die chuck 104 to the first plunger 108 may repeat for each die pickup operation. The flexible wafer chuck 100 may comprise a movable platform equipped with precision X-Y-Z positioning capabilities and rotational control. The movable platform allows the flexible wafer chuck 100 to move precisely between the first plunger 108 and the die chuck 104, enabling accurate positioning of the target bonding locations.

In an alternative embodiment, an alignment system may be coupled to the die chuck 104 and the local protruding system 130. The alignment system may comprise optical sensors and precision actuators configured to align the first plunger 108 relative to the die chuck 104. The alignment system may detect and measure the relative positions of the first plunger 108 and the die chuck 104, making automatic adjustments to achieve precise alignment. Once aligned, the first plunger 108 and the die chuck 104 may be fixed at the aligned position for subsequent bonding operations.

In another embodiment, a first alignment controller 122 may be coupled to the first piezoelectric actuator 120 and the support platform 118. The first alignment controller 122 may comprise an optical system configured to detect the precise position of the first piezoelectric actuator 120 and the first plunger 108. In another embodiment, the first alignment controller 122 may comprise a mechanical system configured to move the first piezoelectric actuator 120 to a specified target location on the support platform 118, enabling accurate alignment.

The support platform 118 may be made from rigid materials such as metals, ceramics, high-strength polymers, or the like. In various embodiments, the support platform 118 may be motorized such that it can position the first piezoelectric actuator 120 and the first plunger 108 to the chosen location. The support platform 118 may thus serve as a robust framework to ensure system stability for precise control of the movement of the first plunger 108. This may ensure consistent and precise pressure application on the flexible wafer chuck 100 to form the desired shape and size of the locally protruding region.

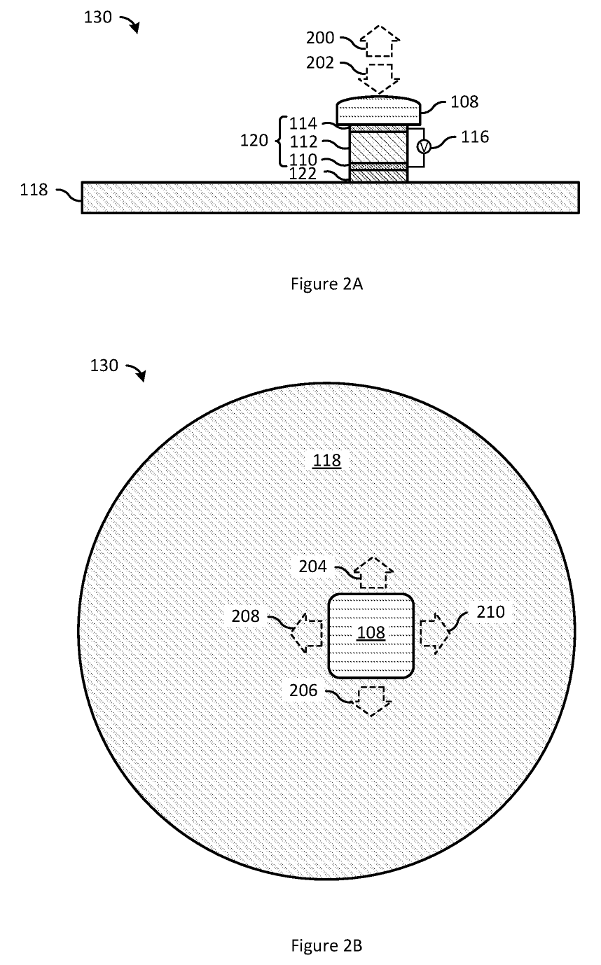

FIG. 2A is a schematic view of the local protruding system 130 illustrated in FIG. 1, in accordance with an embodiment. The local protruding system 130 may comprise the first plunger 108, the first piezoelectric actuator 120, a front end circuit comprising a first alignment controller 122, and the support platform 118.

The first voltage controller 116 may be coupled to the first piezoelectric actuator 120 and may regulate the voltage between the first top electrode 114 and the first bottom electrode 110, thereby adjusting the electric field in the first piezoelectric layer 112. The adjusted electric field may actuate the first piezoelectric layer 112, thus change operational states of the first plunger 108. In some embodiments, the first voltage controller 116 may be controlled by additional hardware and software such as one or more processors executing a program with instructions stored in a memory.

In an embodiment, the first plunger 108 may be in a first operational state to deform the flexible wafer chuck 100 to form a locally protruding region within the chuck and the wafer being supported. The induced pressure is maintained such that the locally protruding region does not introduce plastic deformation within the chuck and the wafer being supported and both the within the chuck and the wafer being supported are elastically deformed.

The first voltage controller 116 may increase the electric field to expand the thickness of the first piezoelectric layer 112, which in turn moves the first plunger 108 in direction 200. The movement in direction 200 may increase the pressure applied by the first plunger 108 to the flexible wafer chuck 100 upon direct contact resulting in the first plunger 108 switching to the first operational state.

In various embodiments, the first voltage controller 116 may be able to switch the first plunger 108 into a second operational state. The first voltage controller 116 may decrease the electric field to decrease the thickness of the first piezoelectric layer 112 which moves the first plunger 108 in direction 202. The movement in direction 202 decreases the pressure applied by the first plunger 108 to the flexible wafer chuck 100 and removes the elastic deformation producing the locally protruding region.

FIG. 2B is a top view of the local protruding system 130, in accordance with an embodiment. The first plunger 108 may move in four additional directions 204, 206, 208 and 210. Different combinations of movement lengths in these directions enable the first plunger 108 to reach any location on the support platform 118 to align to the intended die-to-wafer bonding region on the wafer 102. In various embodiments, the movements in directions 204, 206, 208 and 210 may be precisely controlled by the alignment system, which may be coupled to the die chuck 104 and/or the local protruding system 130 to move one relative to the other. In one or more embodiments, the local protruding system 130 may remain stationary while the die chuck 104 aligns to it. In an embodiment, when the local protruding system 130 moves to a different position, the die chuck 104 may adjust its position to maintain proper alignment with the local protruding system 130. The alignment system may comprise optical sensors and precision actuators configured to align the first plunger 108 relative to the die chuck 104. The alignment system may detect and measure the relative positions of the first plunger 108 and the die chuck 104, making automatic adjustments to achieve precise alignment. In another embodiment, the movements in directions 204, 206, 208 and 210 may be controlled by the first alignment controller 122 coupled to the first piezoelectric actuator 120.

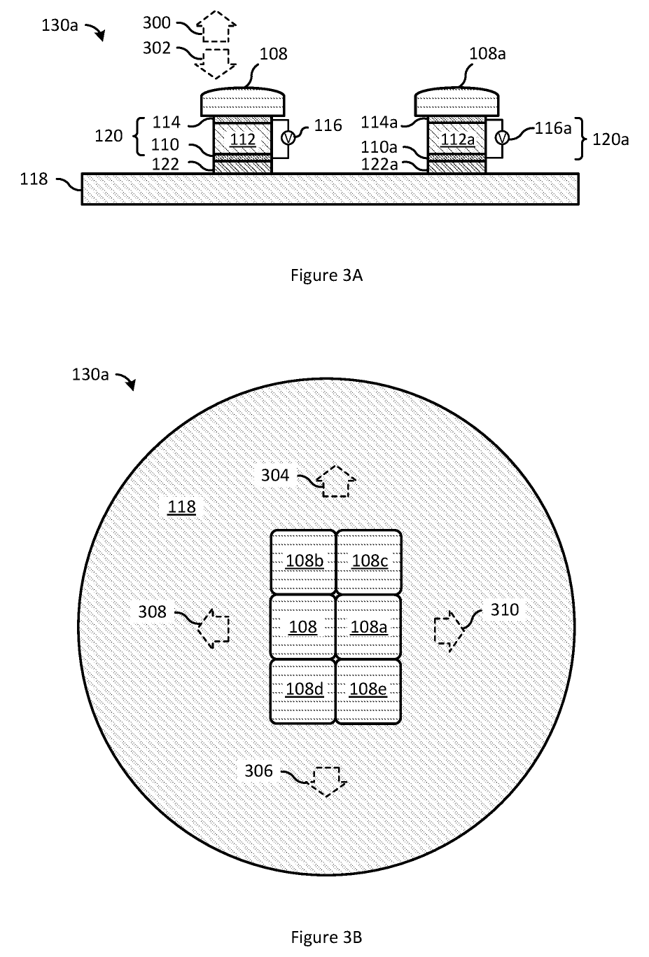

FIG. 3A illustrates a schematic view of a local protruding system 130a as a variation of the local protruding system 130 in FIG. 1, in accordance with an embodiment. The embodiment differs from prior embodiments by including one or more additional plungers into the system.

In some embodiments, the local protruding system 130 may comprise the first plunger 108, the first piezoelectric actuator 120, the first alignment controller 122, a second plunger 108a, a second piezoelectric actuator 120a, a second alignment controller 122a, and the support platform 118. In some embodiments, the first plunger 108 and the second plunger 108a may operate jointly to apply pressure to the flexible wafer chuck 100 to form the locally protruding region on the wafer 102. The local protruding system 130a may further comprise one or more additional plungers, piezoelectric actuators and alignment controllers on the support platform 118.

The first piezoelectric actuator 120 may comprise the first voltage controller 116, the first top electrode 114, the first piezoelectric layer 112, the first bottom electrode 110, and the first piezoelectric layer 112. The first piezoelectric actuator 120 may comprise the materials, structures, and/or other components described above with reference to FIG. 1.

The second piezoelectric actuator 120a may comprise a second voltage controller 116a, a second top electrode 114a, a second bottom electrode 110a, a second piezoelectric layer 112a. The second piezoelectric actuator 120a may be coupled to the second plunger 108a to control its movements in directions 300 and 302.

The second voltage controller 116a may control voltage between the second top electrode 114a and the second bottom electrode 110a so as to actuate the second piezoelectric layer 112a, controlling the movement of the second plunger 108a in directions 300 and 302. The second alignment controller 122a may control the position of the second piezoelectric actuator 120a and the second plunger 108a on the support platform 118.

The second piezoelectric actuator 120a, the second plunger 108a and the second alignment controller 122a may respectively comprise the materials, structures, and/or other components described above with reference to the first piezoelectric actuator 120, the first plunger 108 and the first alignment controller 122 in FIG. 1.

FIG. 3B is a top view of the local protruding system 130a of FIG. 3A, in accordance with an embodiment. The local protruding system 130a may comprise the first plunger 108, the second plunger 108a, a third plunger 108b, a fourth plunger 108c, a fifth plunger 108d, or a sixth plunger 108e. In some embodiments, the local protruding system 130a may comprise more than six plungers. The first, the second, the third, the fourth, the fifth, and the sixth plungers 108, 108a, 108b, 108c, 108d, and 108e may comprise the materials, structures, and/or other components described above with reference to the first plunger 108 in FIG. 1. In some embodiments, the first, the second, the third, the fourth, the fifth, and the sixth plungers 108, 108a, 108b, 108c, 108d, and 108e may have same top surface size and shape such as square or rectangular.

In some embodiments, each of the first, the second, the third, the fourth, the fifth, and the sixth plungers 108, 108a, 108b, 108c, 108d, and 108e may be coupled to a piezoelectric actuator configured to control their movements in directions 300 and 302. These movements may adjust the pressure each plunger applies to the flexible wafer chuck 100.

In various embodiments, each of the first, the second, the third, the fourth, the fifth, and the sixth plungers 108, 108a, 108b, 108c, 108d, and 108e may be coupled to the alignment system to move in directions 304, 306, 308 and 310. The alignment system may be coupled to the die chuck 104 and the local protruding system 130 and may comprise optical sensors and precision actuators configured to align the plungers in FIG. 3B at targeted positions. The alignment system may detect and measure the relative positions of the plungers in FIG. 3B and the die chuck 104, making automatic adjustments to achieve precise alignment. The movements of the first, the second, the third, the fourth, the fifth, and the sixth plungers 108, 108a, 108b, 108c, 108d, and 108e can operate independently, allowing flexibility in both applied pressure and location on the support platform 118.

In some embodiments, one or more of the first, the second, the third, the fourth, the fifth, and the sixth plungers 108, 108a, 108b, 108c, 108d, and 108e may be moved adjacent to each other to jointly apply pressure to the flexible wafer chuck 100. The remaining plungers may not apply pressure. By adjusting combination of the plungers applying pressure together, the top surface of the locally protruding region facing the die 106 can be precisely controlled that may correspond to the footprint of the die 106. This method provides the local protruding system 130a with high flexibility, enabling it to accommodate different scaling requirements of the die 106 during bonding process.

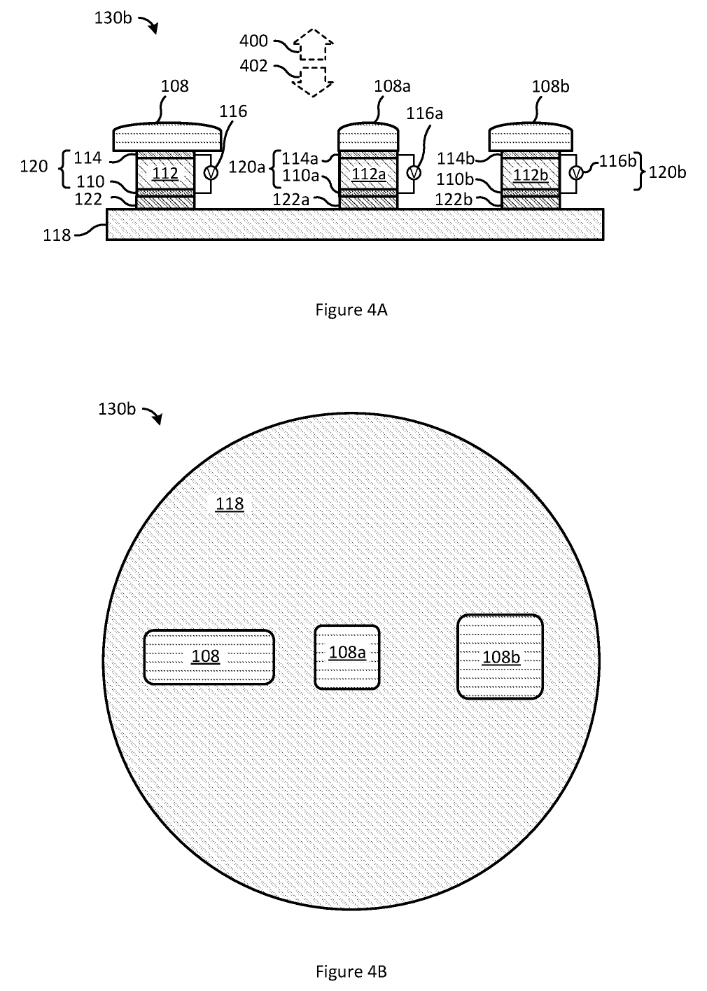

FIG. 4A illustrates a schematic view of a local protruding system 130b as a variation of the local protruding system 130 in FIG. 1, in accordance with an embodiment. The embodiment differs from prior embodiments by including a plurality of plungers that may have different sizes and top surface shapes.

The local protruding system 130b may comprise the first plunger 108, the first piezoelectric actuator 120, the first alignment controller 122, the second plunger 108a, the second piezoelectric actuator 120a, the second alignment controller 122a, a third plunger 108b, a third piezoelectric actuator 120b, a third alignment controller 122b, and the support platform 118. The first, the second, and the third plungers 108, 108a, and 108b may have different top surface sizes and shapes and operate jointly or independently to apply pressure to the flexible wafer chuck 100. In some embodiments, the local protruding system 130b may further comprise one or more additional plungers, piezoelectric actuators and alignment controllers on the support platform 118.

The third piezoelectric actuator 120b may comprise a third voltage controller 116b, a third top electrode 114b, a third bottom electrode 110b, and a third piezoelectric layer 112b. The third piezoelectric actuator 120b may be coupled to the third plunger 108b to control its movements in directions 400 and 402.

The third voltage controller 116b may control the voltage between the third top electrode 114b and the third bottom electrode 110b to actuate the third piezoelectric layer 112b, controlling the movement of the third plunger 108b in directions 400 and 402. The third alignment controller 122b may control the position of the third piezoelectric actuator 120b and the third plunger 108b on the support platform 118.

The third piezoelectric actuator 120b, the third plunger 108b and the third alignment controller 122b may respectively comprise the materials, structures, and/or other components described above with reference to the first piezoelectric actuator 120, the first plunger 108 and the first alignment controller 122 in FIG. 1.

FIG. 4B is a top view of the local protruding system 130b illustrating different top surface shapes and sizes among the first plunger 108, the second plunger 108a and the third plunger 108b, in accordance with an embodiment. The first plunger 108 may feature a rectangular top surface shape, specifically configured to create a locally protruding region on the wafer 102 with rectangular top surface. The second plunger 108a may feature a square top surface shape, specifically configured to create a locally protruding region on the wafer 102 with square top surface. The third plunger 108b may share a square top surface shape but be larger than that of the second plunger 108a. This may create a locally protruding region on the wafer 102 with same square top surface but larger size.

In some embodiments, the local protruding system 130b may further comprise a plurality of plungers with different top surface sizes and shapes, wherein the top surface shapes may comprise circle, triangle, hexagon, octagon, pentagon, parallelogram, or any of the preceding shapes with segments removed in such a way to control the bond rate along different die directions. This diversity in sizes and shapes allows for precise adaptation to various footprints of the die 106.

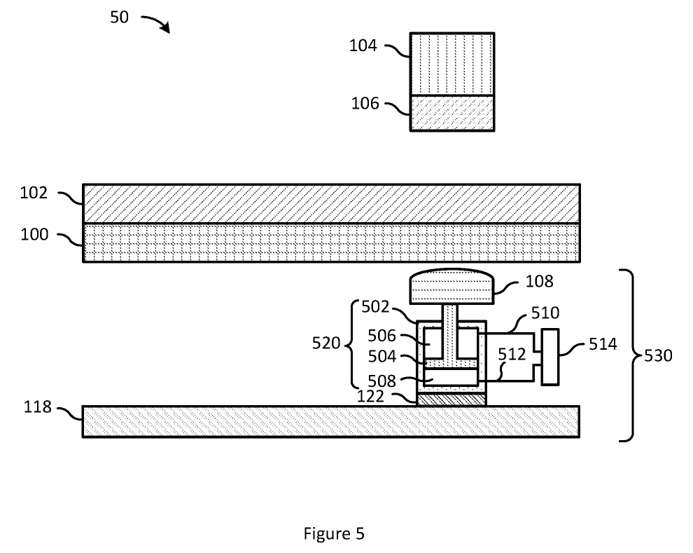

FIG. 5 illustrates a schematic view of a die-to-wafer bonding apparatus 50, as a variation of the apparatus 10 in FIG. 1, in accordance with an embodiment. The embodiment differs from the prior embodiment by including a pneumatic actuator to control the pressure applied by the plunger 108.

The apparatus 50 may comprise the flexible wafer chuck 100 configured to hold the wafer 102, the die chuck 104 configured to hold the die 106. The flexible wafer chuck 100, the wafer 102, the die chuck 104 and the die 106 may respectively comprise the materials, structures, and/or other components described above with reference to corresponding parts of the apparatus 10 in FIG. 1.

The apparatus 50 may further comprise a local protruding system 530 to create the locally protruding area on the wafer 102. The local protruding system 530 may comprise the first plunger 108, a pneumatic actuator 520, the alignment controller 122, and the support platform 118 to apply pressure to the flexible wafer chuck 100.

The first plunger 108 and the support platform 118 may respectively comprise the materials, structures, and/or other components described above with reference to corresponding parts of the apparatus 10 in FIG. 1. The support platform 118 may serve as a robust framework for the pneumatic actuator 520 to provide system stability during operations.

The pneumatic actuator 520 may comprise a chamber 502, which may be separated by a piston 504 into a first sub-chamber 506 and a second sub-chamber 508. The pneumatic actuator 520 may further comprise a first gas flow line 510 coupled to the first sub-chamber 506 and a second gas flow line 512 coupled to the second sub-chamber 508. A gas regulator 514 may be coupled to the first and the second gas flow lines 510 and 512 to control the gas flow to the first and the second sub-chambers 506 and 508. The gas may comprise air, nitrogen, or argon. The pneumatic actuator 520 may be coupled to the first plunger 108 through the piston 504. The movement of the piston 504 may cause the corresponding movement of the first plunger 108.

The chamber 502 may be enclosed by a chamber wall comprising a lining material with high mechanical strength, such as stainless steel, alumina, Teflon quartz, titanium, high-strength polymers such as polyetherimide, aramid, polyethylene, or the like. These materials may provide durability and reliability in maintaining the chamber's integrity under high pressure operations.

The piston 504 may be partially situated within the chamber 502 and configured to separate the chamber 502 into the first sub-chamber 506 and the second sub-chamber 508. When a pressure differential forms between the first sub-chamber 506 and the second sub-chamber 508, the piston 504 may be moved until the pressure differential reduces to zero.

The piston 504 may comprise high-strength materials such as stainless steel, aluminum, Teflon quartz, titanium, high-strength polymers such as polyetherimide, aramid, polyethylene, or the like. These high-strength materials may provide the piston 504 with high durability to withstand repeated stress and pressure changes during actuator operation. The piston 504 may also comprise seals made from resilient polymers such as polytetrafluoroethylene (PTFE), silicone rubber, nitrile rubber, neoprene, or the like. These seals may help achieve an airtight fit with the wall of the chamber 502 to prevent gas leakage.

Moreover, the piston 504 may be partially extending outside the chamber 502 to engage with external components. In some embodiments, the piston 504 may be coupled to the first plunger 108 outside of the chamber 502. The pressure changes within the chamber 502 can be effectively translated into mechanical movement of the first plunger 108.

The gas regulator 514 may control the pressures of the first sub-chamber 506 and the second sub-chamber 508 through the first gas flow line 510 and the second gas flow line 512, respectively. The gas regulator 514 may precisely adjust the flow rates and pressure levels to achieve the desired pressure differential necessary for the movement of the piston 504, which may adjust the operational states of the first plunger 108.

In one embodiment, the first plunger 108 may be in the first operational state to deform the flexible wafer chuck 100 and a wafer that is being supported to form a locally protruding region in the flexible wafer chuck 100 and the wafer due to elastic deformation. The pressure in the first sub-chamber 506 may be lower than that in the second sub-chamber 508. This pressure differential may push the piston 504, causing the first plunger 108 to move towards the flexible wafer chuck 100, and applying pressure. In another embodiment, the first plunger 108 may be switched into the second operational state to remove the locally protruding region. The pressure in the first sub-chamber 506 may be higher than that in the second sub-chamber 508. This pressure differential may cause the first plunger 108 to move away from the flexible wafer chuck 100 to remove pressure which eliminates the elastic deformation of the flexible wafer chuck 100 and the wafer. The pressure differentials may, in various embodiments, be precisely controlled so as to maintain the deformed region of the flexible wafer chuck 100 and the wafer within the elastic regime.

In various embodiments, the die chuck 104 may maintain consistent alignment with the first plunger 108. During operation, the die chuck 104 may move to pick up the die 106 and return to align with the first plunger 108 at a predetermined position. In one or more embodiments, the alignment of the die chuck 104 to the first plunger 108 may repeat for each die pickup operation. The flexible wafer chuck 100 may comprise a movable platform equipped with precision X-Y-Z positioning capabilities and rotational control. The movable platform allows the flexible wafer chuck 100 to move precisely between the first plunger 108 and the die chuck 104, enabling accurate positioning of the target bonding locations.

In an alternative embodiment, an alignment system may be coupled to the die chuck 104 and the local protruding system 530. The alignment system may comprise optical sensors and precision actuators configured to align the first plunger 108 relative to the die chuck 104. The alignment system may detect and measure the relative positions of the first plunger 108 and the die chuck 104, making automatic adjustments to achieve precise alignment. Once aligned, the first plunger 108 and the die chuck 104 may be fixed at the aligned position for subsequent bonding operations.

In another embodiment, the first alignment controller 122 may be coupled to the pneumatic actuator 520 and the support platform 118. The first alignment controller 122 may comprise an optical system configured to detect the precise position of the pneumatic actuator 520. Additionally, the first alignment controller 122 may comprise a mechanical system configured to move the pneumatic actuator 520 to a specified target location on the support platform 118. This functionality enables the accurate alignment of the plunger 108 with the intended die-to-wafer bonding region on the wafer 102.

In some embodiments, the local protruding system 530 may further comprise additional plungers, pneumatic actuators, alignment controllers to independently or jointly apply pressure to the flexible wafer chuck 100. These plungers may comprise different top surface sizes and shapes.

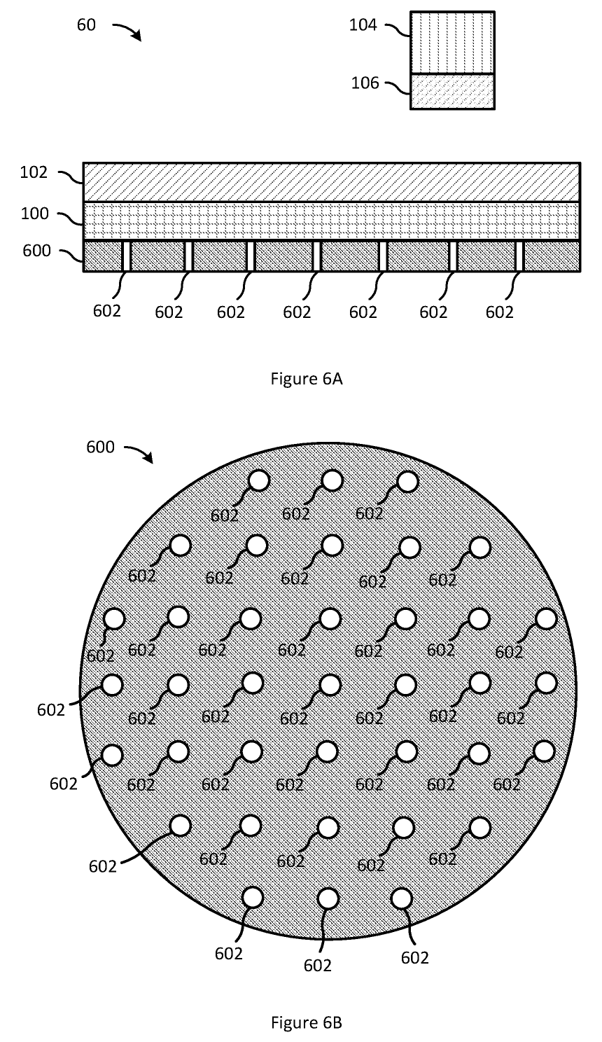

FIG. 6A illustrates a schematic view of a die-to-wafer bonding apparatus 60, as another variation of the apparatus 10 in FIG. 1, in accordance with an embodiment. The embodiment differs from the prior embodiments by utilizing gas pockets to push the flexible wafer chuck 100.

The apparatus 60 may comprise the flexible wafer chuck 100 configured to hold the wafer 102, the die chuck 104 configured to hold the die 106. The flexible wafer chuck 100, the wafer 102, the die chuck 104 and the die 106 may respectively comprise the materials, structures, and/or other components described above with reference to corresponding parts of the apparatus 10 in FIG. 1.

The apparatus 60 may further comprise a channel plate 600 coupled beneath the flexible wafer chuck 100. The channel plate 600 may comprise a plurality of channels 602 to direct vacuum or gas flow. The channel plate 600 may be made from rigid materials comprising stainless steel, aluminum, Teflon quartz, titanium, high-strength polymers such as polyetherimide, aramid, polyethylene, PTFE, or the like. The channel plate 600 may resist deformation when exposed to vacuum or gas flow through the plurality of channels 602.

The plurality of channels 602 may appear as an array of holes on the channel plate 600 from the top view illustrated in FIG. 6B. In some embodiments, a first channel 602 within the channel plate 600 may be coupled to a gas flow line. A second channel 602 within the channel plate 600 may be coupled to a vacuum line. One or more controllers may be configured to deform the flexible wafer chuck 100 to form a locally protruding region by fluidly coupling the gas flow line to a gas tank to form a gas pocket between the flexible wafer chuck 100 and the channel plate 600. To hold the flexible wafer chuck 100 with the channel plate 600, the controllers may couple a vacuum pump to the vacuum line. The gas tank may contain air, nitrogen, or argon.

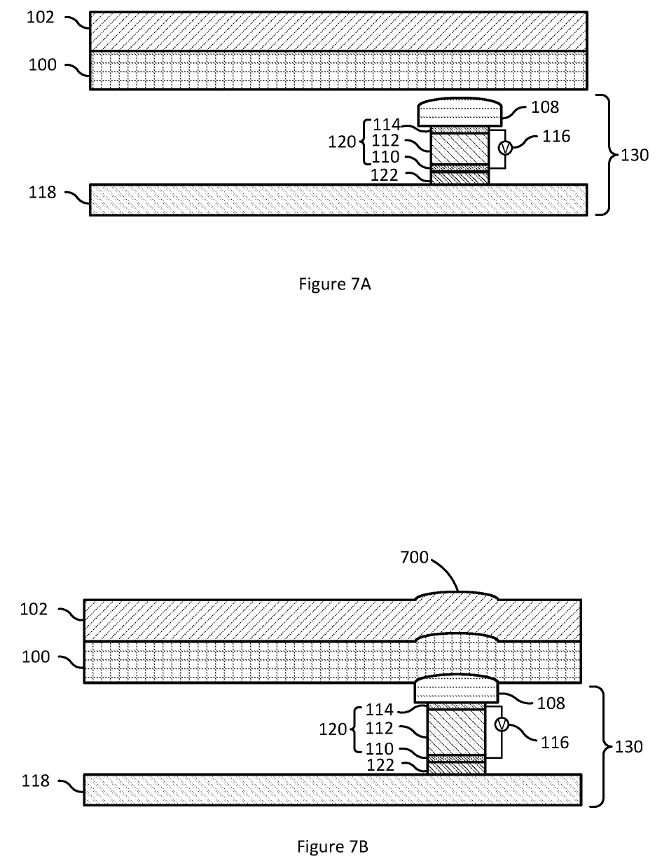

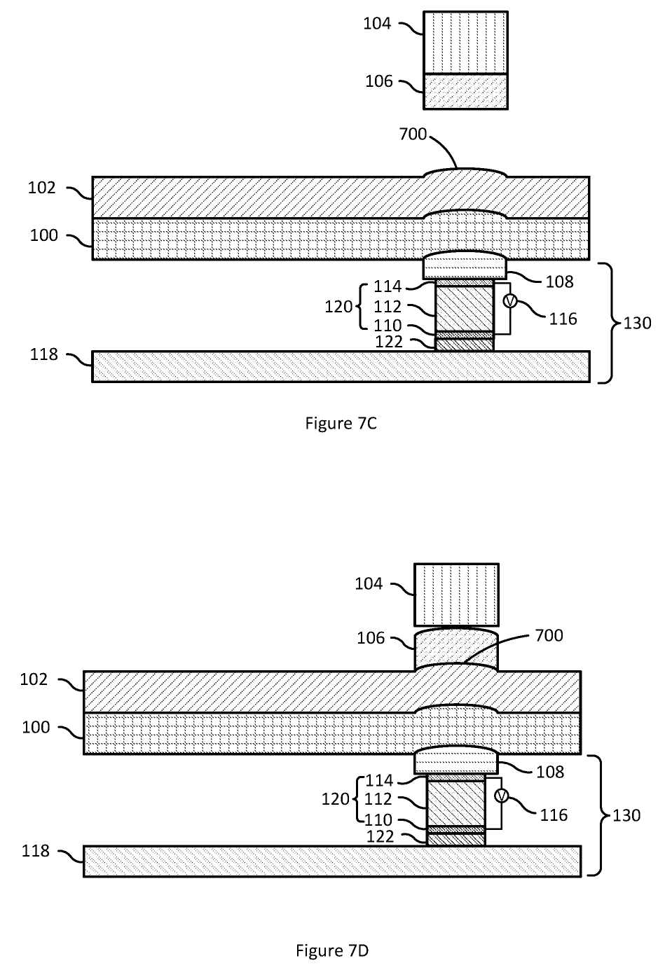

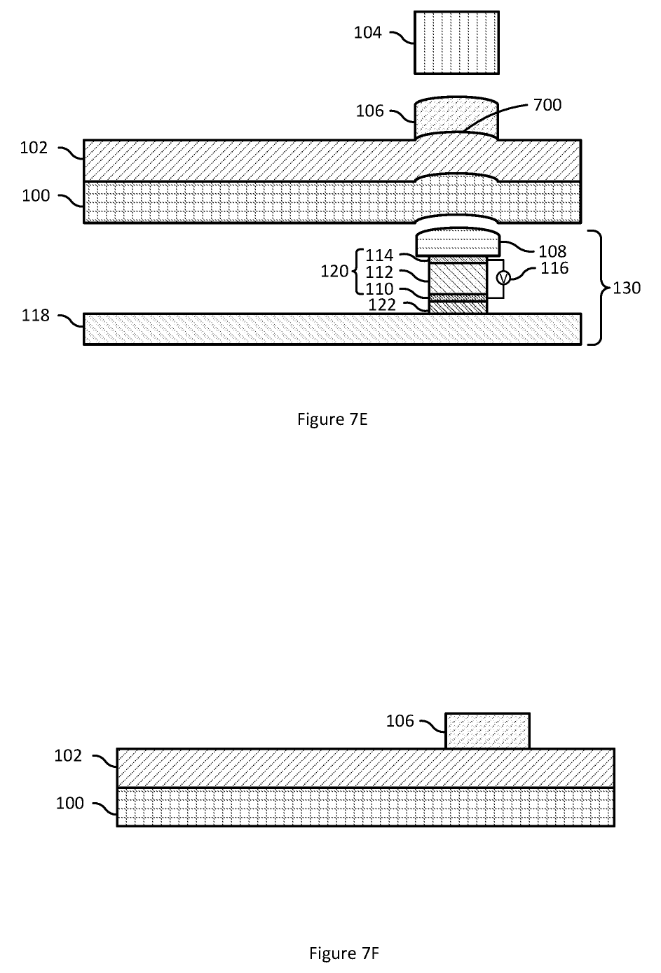

FIGS. 7A-7F are schematic views of a die-to-wafer bonding process using the illustrated apparatus 10 of FIG. 1, in accordance with an embodiment.

In various embodiments, prior to bonding, the surfaces to be bonded may be prepared, e.g., using a wet clean process or a surface plasma activation process.

With reference to FIG. 7A, and according to an embodiment, the wafer 102 may be aligned and placed on a first side of the flexible wafer chuck 100. A vacuum zone may be established between the wafer 102 and the flexible wafer chuck 100 through the vacuum system coupled to the flexible wafer chuck 100. The vacuum zone may ensure that the flexible wafer chuck 100 securely holds the wafer 102 throughout the entire bonding process. The flexible wafer chuck 100 and the wafer 102 may comprise the materials, structures, and/or other components described above with reference to the corresponding parts in FIG. 1.

Afterwards, the local protruding system 130 may be positioned beneath the flexible wafer chuck 100 and configured to apply pressure onto a second side of the flexible wafer chuck 100. The second side is opposite to the first side of the flexible wafer chuck 100. In some embodiments, the local protruding system 130 may comprise the first plunger 108 which is coupled to the first piezoelectric actuator 120. The first piezoelectric actuator 120 may be coupled to the first alignment controller 122. The first alignment controller 122 may move and align the plunger 108 to the specified location on the support platform 118 beneath the intended die-to-wafer bonding region on the wafer 102. In some embodiments, additional plungers may be included in the local protruding system 130 and move collectively to the specified target location to jointly apply pressure to the flexible wafer chuck 100. During this alignment process, the voltage between the first top electrode 114 and the first bottom electrode 110 is set to zero, ensuring no electric field is present in the first piezoelectric layer 112. The local protruding system 130 may comprise the materials, structures, and/or other components described above with reference to the corresponding parts in FIG. 1.

Next, referring to FIG. 7B, the first voltage controller 116 may apply voltage between the first top electrode 114 and the first bottom electrode 110, generating an electric field within the first piezoelectric layer 112. This electric field may cause the first piezoelectric layer 112 to expand in thickness due to the piezoelectric effect, thereby moving the first plunger 108 towards the flexible wafer chuck 100. Once in contact, the first plunger 108 may apply pressure to the flexible wafer chuck 100, inducing the formation of a locally protruding region 700 on the wafer 102. The first voltage controller 116 may continuously adjust the voltage until the top surface of the locally protruding region 700 facing the die 106 align precisely with the footprint of the die 106.

In some embodiments, the first plunger 108 may be replaced or adjusted with plungers of different top surface shapes and sizes to ensure that the top surface of the locally protruding region 700 facing the die 106 can correspond to the footprint of the die 106. This flexibility allows for customization in the bonding process, accommodating dies with unique or complex geometries.

Next, referring to FIG. 7C. The die chuck 104 may hold the die 106 which is configured for bonding with the wafer 102. The die 106 may be securely held by the die chuck 104 through a vacuum zone established between them. The die 106 may be aligned to a position above the locally protruding region 700 on the wafer 102. The die chuck 104 and the die 106 may comprise the materials, structures, and/or other components described above with reference to the corresponding parts in FIG. 1. Prior to bonding, in some embodiments, plasma activation or a fluid such as water may be applied to the surfaces for improved bonding, e.g., improving the strength of the initial van der Waals bond.

With reference to FIG. 7D, a temporary bond between the die 106 and the wafer 102 may be formed, following the alignment process illustrated in FIG. 7C. The die chuck 104 may place the die 106 on the locally protruding region 700 by deactivating the vacuum zone. The die chuck 104 may continue to apply pressure to the die 106, minimizing the gap between the die 106 and the wafer 102. This pressure may enhance van der Waals interactions at the interface between the wafer 102 and the die 106, forming a stable temporary bonding. As the bond forms, the die 106 may undergo scaling to alleviate stress, allowing it to conform precisely to the shape of the locally protruding region 700. This approach can compensate for the scaling of die during the bonding process, thereby improving alignment between wafer and die and enhancing overall device performance.

Next, in FIG. 7E, the die chuck 104 may release the pressure applied to the die 106 and move upward. The first voltage controller 116 may reset the voltage between the first top and the first bottom electrodes 114 and 110 to zero, eliminating the electric field in the first piezoelectric layer 112. This may restore the piezoelectric layer 112 to its original thickness, causing the first plunger 108 to move away from the flexible wafer chuck 100, thereby removing the applied pressure.

In some embodiments, an additional die may be bonded over the die 106, facilitating integrated chip design. The die chuck 104 may align and position the additional die onto the die 106. Afterwards, continuous pressure may be applied by the die chuck 104 to the additional die until a temporary bond forms with the die 106.

Referring to FIG. 7F, a final bonding process between the wafer 102 and the die 106 may be achieved by increasing the temperature of the wafer 102 in a separate processing chamber. In some embodiments, the temperature may be maintained between 100 ºC and 400 ºC. The elevation in temperature may facilitate atomic diffusion at the interface between the wafer 102 and the die 106, forming covalent or ionic bonding that enhance bonding strength and improve device integrity. During this bake process, the van der Waals bond formed during the initial contact are converted into permanent bond.

The die-to-wafer bonding process described above with reference to FIGS. 7A-7F may be combined or adapted to various other apparatus configurations. These steps are designed for versatility, allowing their application across different embodiments to achieve similar functional outcomes. For example, the piezoelectric actuator and its operation detailed herein can be used interchangeably or alongside other actuators such as pneumatic actuators or gas pockets.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for die-to-wafer bonding, the method comprising:
placing a wafer over a first side of a flexible wafer chuck, the flexible wafer chuck comprising the first side and an opposite second side;
pushing, from the second side, the flexible wafer chuck with a first plunger to form a locally protruding region on the wafer;
placing a die on the locally protruding region of the wafer; and
bonding the die to the wafer at the locally protruding region.

2. The method of claim 1, wherein the flexible wafer chuck comprises ceramic materials with an elastic deformation range of 1 micrometer to 100 micrometers.

3. The method of claim 1, wherein a top surface of the locally protruding region facing the die corresponds to a footprint of the die.

4. The method of claim 1, further comprising:
coupling a first piezoelectric actuator to the first plunger, the first piezoelectric actuator comprising a first piezoelectric layer;
applying an electric field within the first piezoelectric layer to actuate the first piezoelectric layer; and
moving the first plunger in response to actuating the first piezoelectric layer, the moving of the first plunger applying the pressure to the flexible wafer chuck.

5. The method of claim 1, further comprising:
coupling a pneumatic actuator to the first plunger, the pneumatic actuator comprising a first sub-chamber and a second sub-chamber separated by a piston;
generating a pressure differential between the first and the second sub-chambers;
moving the piston in response to the pressure differential to move the first plunger, the movement of the first plunger applying the pressure to the flexible wafer chuck.

6. The method of claim 1, further comprising using a second plunger to jointly apply the pressure with the first plunger to the flexible wafer chuck to form the locally protruding region on the wafer.

7. The method of claim 1, further comprising increasing the temperature of the wafer during the bonding.

8. A die-to-wafer bonding apparatus comprising:
a wafer chuck; and
a first plunger configured to be operable in a first operational state and a second operational state, wherein in the first operational state, the first plunger is configured to locally deform the wafer chuck to form a locally protruding region, and wherein in the second operational state, the first plunger is configured to remove the locally protruding region.

9. The apparatus of claim 8, wherein the wafer chuck comprises ceramic materials with an elastic deformation range of 1 micrometer to 100 micrometers.

10. The apparatus of claim 8, further comprising a first piezoelectric actuator coupled to the first plunger, the first piezoelectric actuator being configured to control a pressure applied by the first plunger to the wafer chuck.

11. The apparatus of claim 10, wherein the piezoelectric actuator comprising:
a first bottom electrode;
a first top electrode disposed over the first bottom electrode, the first top electrode being coupled to the first plunger;
a first piezoelectric layer disposed between the first top and the first bottom electrodes; and
a first voltage controller coupled to the first top and the first bottom electrodes, the first voltage controller being configured to apply a voltage between the first top and the first bottom electrodes.

12. The apparatus of claim 8, further comprising a pneumatic actuator coupled to the first plunger, the pneumatic actuator being configured to control a pressure applied by the first plunger to the wafer chuck.

13. The apparatus of claim 8, further comprising a die chuck configured to pick up a die and move to align with the first plunger.

14. The apparatus of claim 8, wherein the first plunger comprises stainless steel, aluminum, alumina, or zirconia.

15. The apparatus of claim 8, further comprising a first alignment controller configured to align the first plunger to the target position for the locally protruding region.

16. The apparatus of claim 8, further comprising a second plunger configured to jointly apply pressure with the first plunger to the wafer chuck to form the locally protruding region.

17. The apparatus of claim 8, further comprising an alignment system configured to align the first plunger at a targeted position.

18. A die-to-wafer bonding apparatus comprising:
a wafer chuck;
a channel plate configured to be coupled to the wafer chuck;
a first channel within the channel plate, wherein the first channel is coupled to a gas flow line;
a second channel within the channel plate, wherein the second channel is coupled to a vacuum line; and
one or more controllers configured to deform the wafer chuck to form a locally protruding region by
coupling a vacuum pump to the vacuum line to hold the wafer chuck with the channel plate; and
fluidly coupling the gas flow line to a gas tank to form a gas pocket between the wafer chuck and the channel plate.

19. The apparatus of claim 18, wherein the gas comprises air, argon, or nitrogen.

20. The apparatus of claim 18, wherein the wafer chuck comprises ceramic materials with an elastic deformation range of 1 micrometer to 100 micrometers.
